(19) United States
(12) Patent Application Publication
(10) Pub. No.: US 2026/0118776 A1
(43) Pub. Date: Apr. 30, 2026

(54) THERMAL CONTROL METHOD FOR PATTERNING DEVICE

(71) Applicant: THE INSTITUTE OF OPTICS AND ELECTRONICS, THE CHINESE ACADEMY OF SCIENCES, Chengdu, Sichuan (CN)

(72) Inventors: Chengwei Zhao, Chengdu, Sichuan (CN); Yanqin Wang, Chengdu, Sichuan (CN); Chuanxin Ren, Chengdu, Sichuan (CN); Tiancheng Gong, Chengdu, Sichuan (CN); Yiyun Zhang, Chengdu, Sichuan (CN); Xiaoan Chen, Chengdu, Sichuan (CN)

(21) Appl. No.: 19/144,073

(22) PCT Filed: Dec. 29, 2022
(86) PCT No.: PCT/CN2022/143396

§ 371 Date: Jun. 27, 2025

(51) Int. Cl. G03F 7/00; G03F 7/20

(52) U.S. Cl. CPC G03F 7/70875; G03F 7/203; G03F 7/70041; G03F 7/70558

(57) ABSTRACT

A thermal control method for a patterning device includes: S1, turning on a compensation illumination, and after heating a patterning device to a heat balance temperature interval, turning off the compensation illumination, the area of a corresponding illumination region being S_{C1×C2}; S2, turning on a first measurement illumination, and after completing the measurement, turning off the first measurement illumination, the area of a corresponding illumination region being S_{D1×D2}; and S₃, turning on an exposure illumination, and after completing the exposure, turning off the exposure illumination, the area of a corresponding illumination region being S_{E1×E2}, S_{C1×C2}≥S_{D1×D2}≥S_{E1×E2}; during the process of mutual switching of S1, S2 and S3, the temperature of the patterning device is kept in the heat balance temperature interval in which a Z-direction deformation quantity of the edge of the compensation illumination region is greater than or equal to 50% of that of the center of the patterning device.

### TECHNICAL FIELD

The present disclosure relates to the technical field of thermal control, and specifically, to a thermal control method for a patterning device.

### BACKGROUND ART

Under light source illumination conditions, a portion of incident light will be absorbed by the patterning device (such as a mask), causing the temperature of the patterning device to rise, thereby generating thermal deformation. The thermal deformation of the patterning device includes X-Y direction deformation and Z-direction deformation. The X-Y direction deformation will cause positional deviation of the mask pattern and is one of the main sources of overlay error. The Z-direction deformation will affect the flatness of the patterning device surface and will also affect the control of the focal plane. The X-Y direction deformation can be corrected by applying force to the outer edge around the mask to adjust, but the Z-direction deformation cannot be corrected by applying external force to the surface. Therefore, the control of deformation in the Z direction is particularly important.

In projection lithography, the thermal deformation of the mask is mainly controlled through a series of thermal control means, including arranging a nitrogen supply system inside the lens group and arranging a water-cooling structure in the mask stage, to improve heat dissipation capacity. However, in traditional proximity lithography or contact lithography, the lithography resolution is low and there is no special requirement for mask temperature control, and operation under laboratory environment is sufficient. However, when the distance between the mask and the substrate is only hundreds of nanometers or less, or even they are in contact state, traditional thermal control means cannot be applied at all. How to control the thermal deformation of the patterning device in the Z direction becomes an urgent problem to be solved.

### SUMMARY

### (I) Technical Problem to be Solved

In view of the above problems, the present disclosure provides a thermal control method for a patterning device, for solving technical problems such as the difficulty in realizing effective thermal control of the patterning device by traditional methods when the distance between the patterning device and the substrate is only hundreds of nanometers or less.

### (ii) Technical Solution

The present disclosure provides a thermal control method for a patterning device, including: S1, turning on compensation illumination, after heating a patterning device to a thermal equilibrium temperature range, turning off the compensation illumination, wherein an illumination region area of the compensation illumination is S_{C1×C2}; S2, turning on first detection illumination, turning off the first detection illumination after a detection step is completed, wherein the illumination region area of the first detection illumination is S_{D1×D2}; and S3, turning on exposure illumination, turning off the exposure illumination after an exposure step is completed, wherein the illumination region area of the exposure illumination is S_{E1×E2}, wherein S_{C1×C2}≥S_{D1×D2}≥S_{E1×E2}, wherein during a switching process among S1, S2 and S3, a temperature of the patterning device is maintained within a thermal equilibrium temperature range; and within the thermal equilibrium temperature range, a Z-direction deformation ΔZ_{C1×C2} at an edge of the compensation illumination region is greater than or equal to 50% of the Z-direction deformation AZ at a center of the patterning device.

Further, before S1, the method also includes: S0, determining the thermal equilibrium temperature range according to a relationship between the deformation and the temperature of the patterning device.

Further, after S3, the method also includes: S4, turning on the exposure illumination in a next exposure field, wherein the temperature of the patterning device is maintained within the thermal equilibrium temperature range during the exposure illumination duration, and a time interval between preceding and succeeding exposure illuminations is T₅.

Further, before S4, the method also includes: S41, turning off all illumination, allowing the patterning device to cool, wherein a cooling duration is T₄; and T₄ includes T₅ or T₄ does not include T₅.

Further, after S3, the method also includes: repeating S2˜S3 to alternately perform the detection step and the exposure step, wherein the patterning device is maintained within the thermal equilibrium temperature range during the detection step and the exposure step.

Further, S1 also includes: turning on second detection illumination when turning on the compensation illumination, wherein the second detection illumination remains turned on during S2˜S3; a thermal output power of the second detection illumination is much lower than a thermal output power of the first detection illumination; and no interference between the second detection illumination and the first detection illumination.

Further, after S3, the method also includes: S41, turning off all illumination, allowing the patterning device to cool, wherein a cooling duration is T₄; and S4, turning on the exposure illumination in a next exposure field, wherein the temperature of the patterning device is maintained within the thermal equilibrium temperature range during the exposure illumination duration; a time interval between preceding and succeeding exposure illuminations is T₅; and T₄ includes T₅ or T₄ does not include T₅.

Further, after S3, the method also includes: repeating S2˜S3 to alternately perform the detection step and the exposure step, wherein the patterning device is maintained within the thermal equilibrium temperature range during the detection step and the exposure step.

Further, S2 also includes: alternately turning on third detection illumination and first detection illumination, wherein a single illumination cycle and a single illumination duration of the third detection illumination match a single illumination cycle and a single illumination duration of the first detection illumination, wherein an interference exists between the third detection illumination and the first detection illumination.

Further, after S3, the method also includes: repeating S2˜S3, wherein only the third detection illumination in S2 is turned on during the repeating process, and the first detection illumination is turned off; and alternately performing the detection step and the exposure step, wherein the patterning device is maintained within the thermal equilibrium temperature range during the detection step and the exposure step.

### (iii) Beneficial Effects

The thermal control method for a patterning device of the present disclosure is provided. On the basis of detection illumination and exposure illumination, the method introduces compensation illumination, ensuring that the temperature of the patterning device is within the thermal equilibrium temperature range when switching among various illumination modes. Therefore, the temperature fluctuation is small, realizing long-term maintenance of thermal equilibrium of the patterning device, so that the patterning device can maintain uniform and stable deformation in the Z direction. At the same time, through reasonable duration of various illumination modes, matching illumination intensity, frequency, and cooling duration of different illumination light sources, switching among various illumination modes is realized, thereby improving exposure efficiency.

### BRIEF DESCRIPTION OF DRAWINGS

FIG. 1 schematically illustrates a flowchart of a thermal control method for a patterning device according to an embodiment of the present disclosure;

FIG. 2 schematically illustrates a structural schematic diagram of an exposure system according to an embodiment of the present disclosure;

FIG. 3 schematically illustrates a schematic diagram of an energy transfer process in a patterning device according to an embodiment of the present disclosure;

FIG. 4 schematically illustrates a schematic diagram of a timing switching process of various illuminations in one solution according to an embodiment of the present disclosure;

FIG. 5 schematically illustrates a top view of a patterning device according to an embodiment of the present disclosure;

FIG. 6 schematically illustrates a schematic diagram of a timing switching process of various illuminations in another solution according to an embodiment of the present disclosure;

FIG. 7 schematically illustrates a schematic diagram of a timing switching process of various illuminations in another solution according to an embodiment of the present disclosure;

FIG. 8 schematically illustrates a schematic diagram of a timing switching process of various illuminations in another solution according to an embodiment of the present disclosure;

FIG. 9 schematically illustrates a schematic diagram of a timing switching process of various illuminations in another solution according to an embodiment of the present disclosure;

FIG. 10 schematically illustrates a schematic diagram of a timing switching process of various illuminations in another solution according to an embodiment of the present disclosure;

FIG. 11 schematically illustrates a schematic diagram of a timing switching process of various illuminations in another solution according to an embodiment of the present disclosure;

FIG. 12 schematically illustrates a schematic diagram of a timing switching process of various illuminations according to an embodiment of the present disclosure;

FIG. 13 schematically illustrates a top view of a patterning device according to an embodiment of the present disclosure;

FIG. 14 schematically illustrates a schematic diagram of temperature variation of a patterning device according to an embodiment of the present disclosure; and

FIG. 15 schematically illustrates a schematic diagram of temperature variation of a patterning device without adopting the thermal control method of the present disclosure.

### REFERENCE NUMERALS

1—patterning device; 1-1—first air layer; 1-2—patterning device substrate; 1-3—pattern film layer; 1-4—second air layer; 1-5—first interface layer; 1-6—absorption layer; 1-7—second interface layer; 2—chuck; 3—substrate; 4—stage; 5-1-1—second detection illumination; 5-1-2—third detection illumination; 5-2—first detection illumination; 5-3—exposure illumination; 5-4—compensation illumination.

### DETAILED DESCRIPTION OF EMBODIMENTS

In order to make the objectives, technical solutions, and advantages of the present disclosure clearer and more understandable, the present disclosure is described in further detail hereinafter in connection with specific embodiments and with reference to the drawings.

The terminology used herein is only for describing specific embodiments and is not intended to limit the present disclosure. The terms “comprise”, “include”, and the like as used herein indicate the presence of the features, steps, operations, and/or components, but do not preclude the presence or addition of one or more other features, steps, operations, or components.

It should be noted that, if directional indications are involved in the embodiments of the present disclosure, such directional indications are only used to explain the relative positional relationships, movement conditions, etc. among components in a specific posture. If the specific posture changes, then the directional indications also change accordingly.

The ordinal terms used in the specification and claims, such as “first”, “second”, “third”, etc., are used to modify the corresponding elements. These terms themselves do not imply or represent any ordinal meaning of the elements, nor do they indicate the sequence between elements or the order in manufacturing methods. The use of such ordinal terms is only intended to clearly distinguish one element with a certain designation from another element with the same designation.

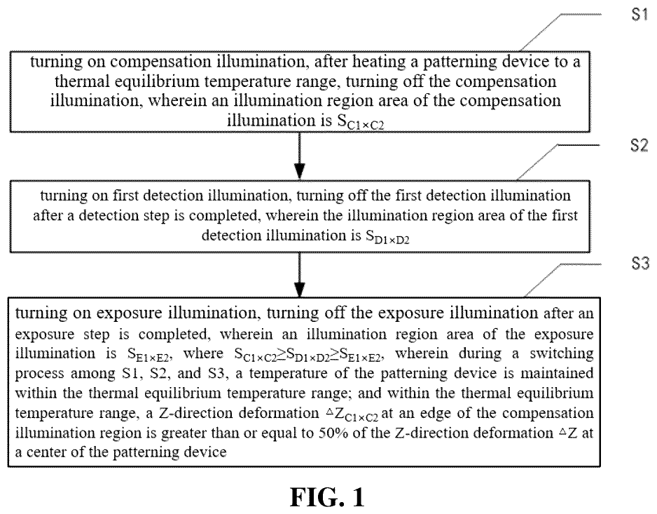

The present disclosure provides a thermal control method for a patterning device, as shown in FIG. 1, including: S1, turning on compensation illumination 5-4, after heating a patterning device 1 to a thermal equilibrium temperature range, turning off the compensation illumination 5-4, wherein an illumination region area of the compensation illumination 5-4 is S_{C1×C2}; S2, turning on first detection illumination 5-2, turning off the first detection illumination 5-2 after a detection step is completed, wherein the illumination region area of the first detection illumination 5-2 is S_{D1×D2}; and S3, turning on exposure illumination 5-3, turning off the exposure illumination 5-3 after an exposure step is completed, wherein the illumination region area of the exposure illumination 5-3 is S_{E1×E2}, wherein S_{C1×C2}≥S_{D1×D2}≥S_{E1×E2}, wherein during a switching process among S1, S2 and S3, a temperature of the patterning device 1 is maintained within a thermal equilibrium temperature range; and within the thermal equilibrium temperature range, a Z-direction deformation ΔZ_{C1×C2} at an edge of the compensation illumination region is greater than or equal to 50% of the Z-direction deformation ΔZ at a center of the patterning device.

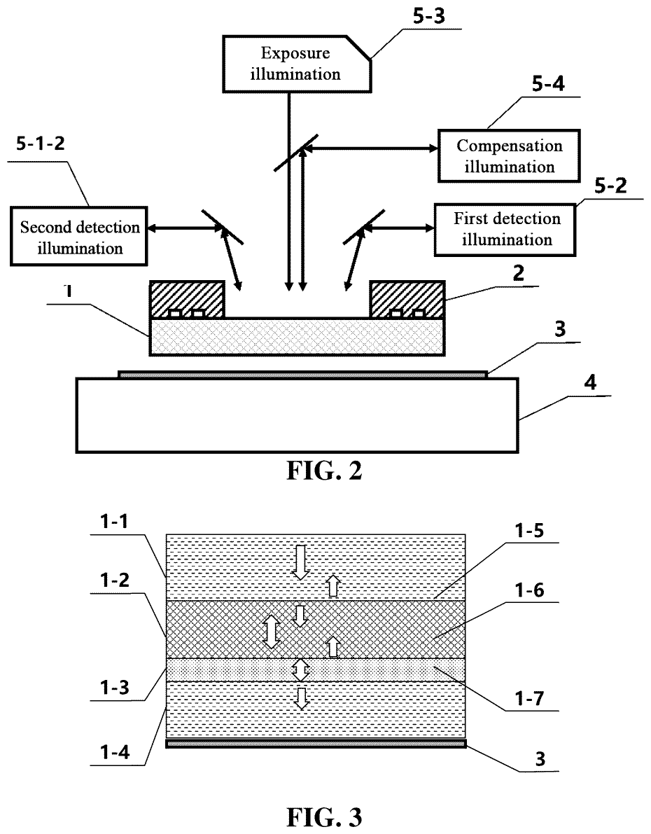

The thermal control method of the present disclosure can be applied in exposure apparatus such as contact lithography, proximity lithography, or near-field lithography. As an example, as shown in FIG. 2, in the near-field lithography system, the patterning device 1 is adsorbed and mounted on the chuck 2, and the substrate 3 is mounted on the stage 4. The patterning device 1 is affected by the thermal load of the first detection illumination 5-2, exposure illumination 5-3, and compensation illumination 5-4. The first detection illumination 5-2 is configured for acquiring position information, the exposure illumination 5-3 is configured for providing light required for exposure, and the compensation illumination 5-4 is configured for heating the upper-side patterning device 1, so as to rapidly reach a thermal equilibrium state. The compensation illumination 5-4 can be an additional illumination system, or the existing first detection illumination 5-2 can be used. For the convenience of subsequent description, the illumination, configured for performing the function of heating the upper-side patterning device 1, is referred to as the compensation illumination 5-4. Since the distance between the patterning device 1 and the substrate 3 is only at a level of hundreds of nanometers or less, or even they are in a contact state, it is not possible to design a heat dissipation system below the patterning device 1. In order to maximize the heat dissipation capacity of the patterning device, the chuck 2 is selected made of a material with high stiffness and low thermal expansion coefficient, with priority given to materials such as microcrystalline glass, silicon carbide, and alumina.

As shown in FIG. 3, in the illumination region, the upper side of the pattern forming device 1 is a first air layer 1-1. The patterning device 1 is composed of a patterning device substrate 1-2 and a pattern film layer 1-3. The lower side of the patterning device 1 is a second air layer 1-4. The heat absorption region can be divided into a first interface layer 1-5, an absorption layer 1-6, and a second interface layer 1-7. The first interface layer 1-5 is the interface between the patterning device substrate 1-2 and the first air layer 1-1, with a heat absorption rate of A % and a heat return rate of B %. The absorption layer 1-6 is the patterning device substrate 1-2, with a heat absorption rate of C %. Since the thickness of the pattern film layer 1-3 is only tens to hundreds of nanometers, the second interface layer 1-7, in the case of including the pattern film layer 1-3, is the interface between the patterning device substrate 1-2 and the second air layer 1-4, with a heat absorption rate of D %. The heat absorption rate of the second air layer 1-4 is E %. The sum of A %, B %, C %, D %, and E % is 100%.

An exposure imaging simulation analysis shows that a relatively large proportion of heat is reflected back into the first air layer 1-1 (that is, the B value is relatively larger). The patterning device substrate 1-2 itself has a high transmittance and absorbs very little heat (that is, the C value is smaller). The heat absorption of the patterning device 1 is mainly concentrated in the pattern film layer 1-3 (that is, the D value is larger). At room temperature, the thermal conductivity of the absorption layer 1-6 is 1.3 W/(m·° C.), and during the exposure illumination duration which is only on the order of seconds or even less, heat cannot be timely transferred to the first interface layer 1-5 between the patterning device substrate 1-2 and the first air layer 1-1. The patterning device 1 and the substrate 3, at a distance of hundreds of nanometers, exchange heat through contact with air, and the heat transfer coefficient is as low as 5×10⁻⁶ W/(mm²·° C.). Therefore, most of the heat on the lower surface of the patterning device 1 can still only be slowly transferred to the upper surface. Since the heat cannot be dissipated in time, the method of thermal equilibrium is adopted for heat control. The thermal equilibrium method maintains the temperature of the patterning device 1 fluctuating within a small range by switching different illuminations at different times. Therefore, after the overall thermal deformation of the pattern forming device 1, the deformation difference in the Z-direction between the central position and the edge position is smaller. The fluctuation deterioration degree of the overall surface shape is smaller, thereby avoiding position error caused by non-uniform deformation in Z direction, and unexpected and excessive deformation occurring in the processed pattern.

That is, the thermal control method starts from the heat source, and based on the first detection illumination 5-2 and the exposure illumination 5-3, introduces compensation illumination 5-4, so that the temperature of the patterning device 1 (for example, a mask) rapidly rises to the thermal equilibrium temperature range. In the thermal equilibrium temperature range, the patterning device 1 is in a thermal equilibrium state. At this time, the patterning device 1 completes continuous, uniform, and stable deformation in Z direction. It avoids, during subsequent detection and exposure processes, the introduction of illumination heat without temperature control of the patterning device, which would otherwise result in large deformation fluctuations of the patterning device 1 and thereby cause excessive pattern position deviation of the patterning device 1 during detection and exposure. The present disclosure realizes long-time maintenance of thermal equilibrium for the patterning device 1, so that the pattern of the patterning device 1 can maintain uniform and stable deformation. The present disclosure provides an effective thermal control means, which satisfies the requirements of temperature gradient difference and surface shape influence control required by exposure. At the same time, through reasonable duration of various illumination modes, and matching illumination intensity, frequency, and cooling duration of different illumination light sources, switching among various illumination modes is realized, thereby improving exposure efficiency.

Based on the above embodiment, before S1, the method also includes: S0, determining the thermal equilibrium temperature range according to a relationship between the deformation and the temperature of the patterning device 1.

First, the thermal equilibrium temperature range W of the patterning device 1 is determined. The patterning device 1 undergoes thermal deformation, and the relationship between the deformation and temperature of the patterning device 1 can be obtained through experiments or simulation. When, within a temperature range, the Z-direction deformation at the edge of the patterning device 1 is greater than or equal to 50% of the Z-direction deformation at the center, this temperature range can be taken as the thermal equilibrium temperature range W. To utilize the energy of the compensation illumination more efficiently, compensation illumination is usually not applied to the entire region of the patterning device 1. Therefore, the area of the compensation illumination region is usually smaller than the area of the patterning device 1. In this case, the thermal equilibrium temperature range W corresponds to the temperature range in which the Z-direction deformation ΔZ_{C1×C2} at the edge of the compensation illumination region is greater than or equal to 50% of the Z-direction deformation ΔZ at the center of the patterning device.

In the following schematic diagrams of the timing switching processes, the lengths of time and the levels of power density are for illustrative reference only and should not be considered as limitations of actual values.

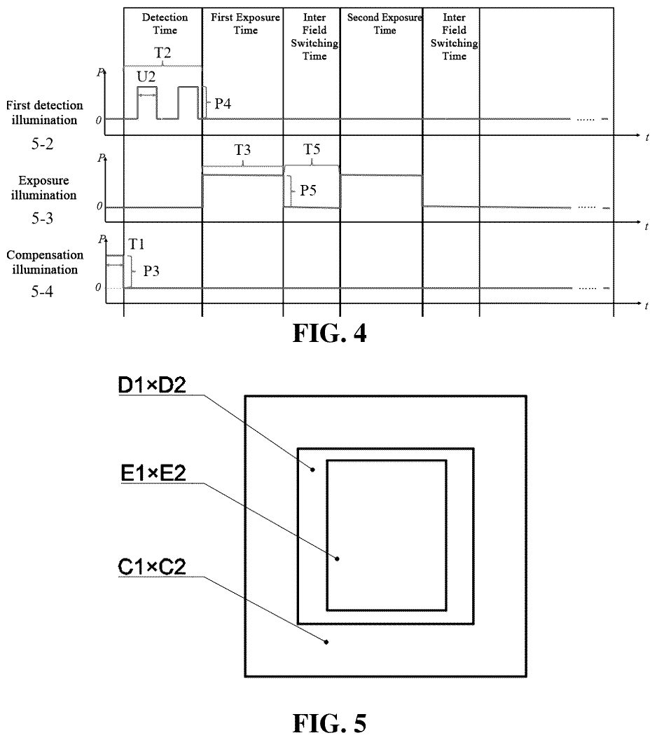

After determining the thermal equilibrium temperature range W, as shown in FIG. 4 (first solution), step S1 continues, including: turning on the compensation illumination 5-4 simultaneously at power-on, with the illumination region of the compensation illumination 5-4 being C1×C2, power density being P3, and illumination time being T1; continuously illuminating until the patterning device 1 reaches the thermal equilibrium temperature range W; and then turning off the compensation illumination 5-4. The compensation illumination 5-4 is configured for heating the patterning device 1 from room temperature to the thermal equilibrium temperature range W, thereby avoiding, when introducing the first detection illumination 5-2 later without controlling the temperature of the pattern formation device 1, the difference of the deformation between the center of the detection region and edge of the detection region becoming too large.

Step S2 includes: turning on the first detection illumination 5-2, wherein the illumination region of the first detection illumination 5-2 is D1×D2, power density is P4, single illumination cycle is T, single illumination duration is U2, wherein in a single field detection, the detection time is T2; and after the single field illumination time reaches T2, completing the position information detection and turning off the first detection illumination 5-2. The first detection illumination 5-2 maintains the temperature of the patterning device 1 within the thermal equilibrium temperature range during its operation.

Step S3 includes: turning on the exposure illumination 5-3, wherein the illumination region of the exposure illumination 5-3 is E1×E2, power density is P5, and single field illumination time is T3; and after the single field illumination time reaches T3, completing exposure and turning off the exposure illumination 5-3. During the switching process between the first detection illumination 5-2 and the exposure illumination 5-3, and in step S3, the temperature of the patterning device 1 is maintained within the thermal equilibrium temperature range.

The top view of the patterning device 1 is shown in FIG. 5, wherein C1×C2 is the compensation illumination region of the patterning device 1, D1×D2 is the region where test marks are processed, and E1×E2 is the pattern surface region of the patterning device 1. S_{C1×C2}≥S_{D1×D2}≥S_{E1×E2}, where S_{C1×C2} represents the area of the region C1×C2, S_{D1×D2} represents the area of the region D1×D2, and S_{E1×E2} represents the area of the region E1×E2. The illumination region area of the compensation illumination 5-4 is the largest (when the first detection illumination 5-2 is used as the compensation illumination, the illumination region area of the compensation illumination 5-4 is equal to the illumination region area of the first detection illumination 5-2). Therefore, the compensation illumination can uniformly heat the patterning device 1, making the temperature within the compensation illumination region more uniform, all within the thermal equilibrium temperature range W.

Based on the above embodiment, after S3, the method also includes: S4, moving the substrate 3 to the next exposure field, turning on the exposure illumination 5-3, wherein the temperature of the patterning device 1 is maintained within the thermal equilibrium temperature range during an illumination duration of the exposure illumination 5-3, and a time interval between two exposure illuminations is T₅.

The stage 4 drives the substrate 3 to move to the next exposure field to continue the next exposure, and the next exposure illumination is turned on; and in this way, subsequent switching of exposure illumination ensures that the energy output to the patterning device 1 within the unit time of the new exposure illumination is consistent with the previous one. The time interval between turning on the exposure illuminations 5-3 of the previous and next fields is T₅, which is the inter-field switching time. Since the patterning device 1 exchanges heat with air with poor efficiency, the temperature variation within the inter-field switching time T₅ is small. If replacing the patterning device 1, the process needs to return to step S1. Since the newly replaced patterning device is at room temperature, the compensation illumination 5-4 is required again to heat the patterning device 1 to the thermal equilibrium temperature range W.

Based on the above embodiment, before S4, the method also includes: S41, turning off all illumination, allowing the patterning device 1 to cool, wherein a cooling duration is T₄; and T₄ includes T₅ or T₄ does not include T₅.

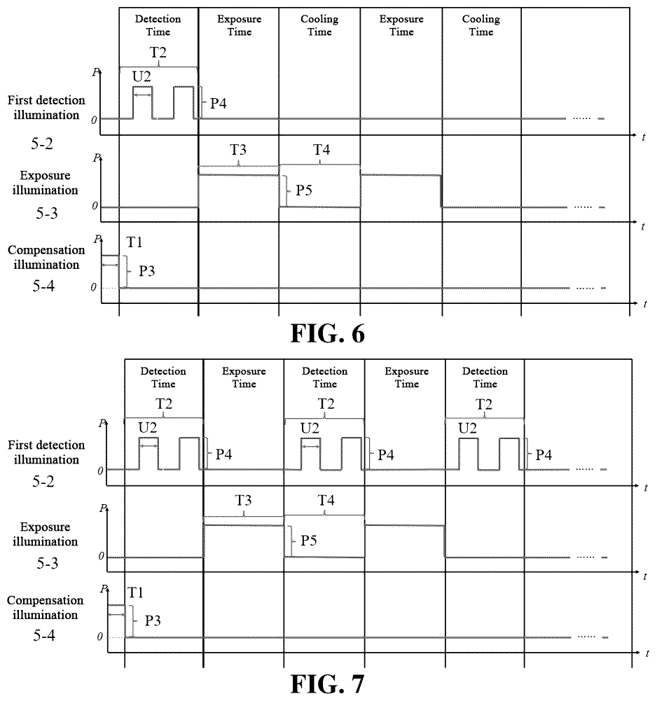

Ideally, during the switching process between the first detection illumination 5-2 and the exposure illumination 5-3, the temperature does not jump and remains within the thermal equilibrium temperature range W. However, in order to ensure the quality of the pattern development after exposure, the exposure illumination time T3 is relatively long, resulting in a large amount of energy being output by the exposure illumination 5-3 to the patterning device 1. In this case, the temperature of the patterning device 1 will rise to near the upper limit of the thermal equilibrium temperature range. Therefore, to avoid the temperature exceeding the upper limit of the thermal equilibrium temperature range during the next exposure process, a cooling process can be added after the exposure step to lower the temperature away from the upper limit of the thermal equilibrium temperature range. During this cooling process, all illuminations are turned off. Specifically, a cooling step S41 is added after step S3. Step S4 can be performed after the completion of this cooling step, or step S4 can be performed during the cooling step, i.e., the cooling and moving to the next exposure field are performed simultaneously. The timing switching process is shown in FIG. 6 (second solution), where all illuminations are turned off, and the cooling time is T4.

Based on the above embodiment, after S3, the method also includes: repeating S2˜S3 to alternately perform the detection step and the exposure step, wherein the patterning device 1 is maintained within the thermal equilibrium temperature range during the detection step and the exposure step.

In the above embodiment, after a single position detection is performed on a single patterning device 1, subsequent multiple exposure fields can be processed. If the detection is required again after the end of the single exposure field, the process needs to return to step S2 after step S3 (or step S41 if it exists). The timing switching process is shown in FIG. 7 (third solution).

On the basis of the above embodiment, step S1 further includes: turning on second detection illumination when turning on the compensation illumination 5-4, wherein the second detection illumination 5-1-1 remains turned on during S2˜S3. The thermal output power of the second detection illumination 5-1-1 is much smaller than the thermal output power of the first detection illumination 5-2, that is, the heat input from the second detection illumination 5-1-1 to the patterning device 1 has basically no effect on its surface shape. Moreover, there is no interference between the second detection illumination 5-1-1 and the first detection illumination 5-2, that is, whether the second detection illumination 5-1-1 is turned on or not does not affect the detection effect of the first detection illumination 5-2.

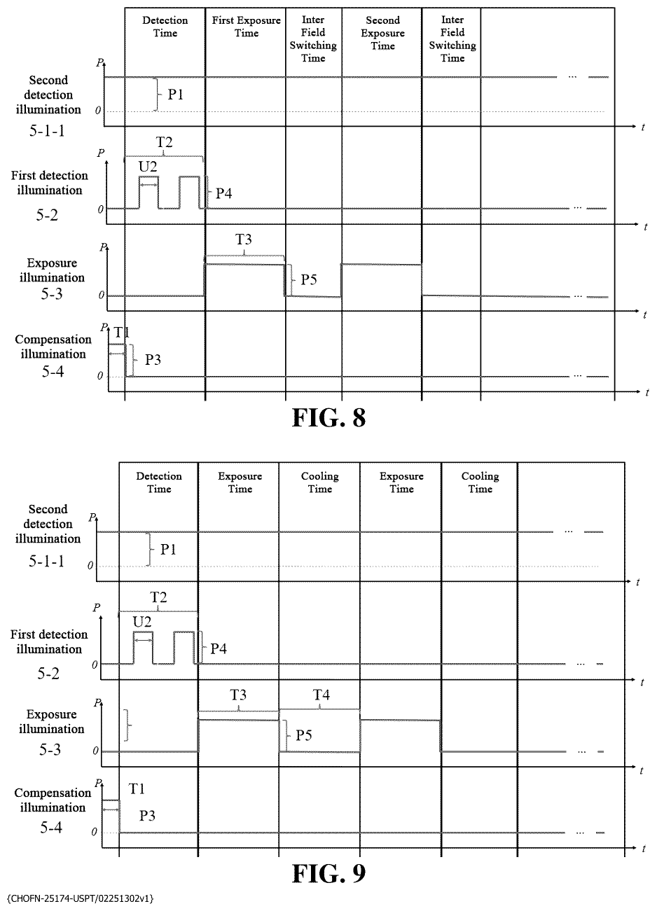

Based on the first solution, in order to expand the applicable scenarios of the above thermal control method, based on the difference in thermal input from detection, the detection illuminations with different detection functions are classified into a first detection illumination 5-2 with high thermal output power and a second detection illumination 5-1-1 with low thermal output power. Since the second detection illumination 5-1-1 with low thermal output power has little effect on the thermal deformation of the patterning device 1, this illumination can remain continuously turned on, and is referred to as continuous detection illumination. Referring to FIG. 8, the complete process is as follows.

Step S1 includes: turning on the second detection illumination 5-1-1 and the compensation illumination 5-4 simultaneously at power-on, wherein since the thermal output from the second detection illumination 5-1-1 to the patterning device 1 is small, its illumination region can be determined based on actual needs, wherein the illumination region of the compensation illumination 5-4 is C1×C2, power density is P3, and illumination time is T1; continuously illuminating until the patterning device 1 reaches the thermal equilibrium temperature range W; and then turning off the compensation illumination 5-4.

Step S2 includes: turning on the first detection illumination 5-2, wherein the illumination region of the first detection illumination 5-2 is D1×D2, power density is P4, single illumination cycle is T, single illumination duration is U2, wherein in a single field detection, the detection time is T2; and after the single field illumination time reaches T2, turning off the first detection illumination 5-2. The first detection illumination 5-2 maintains the temperature of the patterning device 1 within the thermal equilibrium temperature range during its operation.

Step S3 includes: turning on the exposure illumination 5-3, wherein the illumination region of the exposure illumination 5-3 is E1×E2, power density is P5, and single field illumination time is T3; and after the single field illumination time reaches T3, turning off the exposure illumination 5-3. During the switching process between the first detection illumination 5-2 and the exposure illumination 5-3, and in step S3, the temperature of the patterning device 1 is maintained within the thermal equilibrium temperature range.

Based on the above embodiment, after S3, the method also includes: S4, moving the substrate 3 to the next exposure field, turning on the exposure illumination 5-3, wherein, during the illumination duration of the exposure illumination 5-3, the energy output to the patterning device 1 is the same as the energy output to the patterning device 1 in the previous exposure field, and a time interval between two exposure illuminations is T5, i.e., the inter-field switching time.

Ideally, during the switching process between the first detection illumination 5-2 and the exposure illumination 5-3, the temperature does not jump and remains within the thermal equilibrium temperature range W. However, in order to ensure the quality of the pattern development after exposure, the exposure illumination time T3 is relatively long, resulting in a large amount of energy being output by the exposure illumination 5-3 to the patterning device 1. In this case, the temperature of the patterning device 1 will rise to near the upper limit of the thermal equilibrium temperature range. Therefore, to avoid the temperature exceeding the upper limit of the thermal equilibrium temperature range during the next exposure process, a cooling process can be added after the exposure step to lower the temperature away from the upper limit of the thermal equilibrium temperature range. During this cooling process, all illuminations are turned off. Specifically, a cooling step S41 is added after step S3. Step S4 can be performed after the completion of this cooling step, or step S4 can be performed during the cooling step, i.e., the cooling and moving to the next exposure field are performed simultaneously. The timing switching process without a cooling step is shown in FIG. 8 (fourth solution), and the timing switching process with a cooling step is shown in FIG. 9 (fifth solution). Then, the first detection illumination 5-2, the exposure illumination 5-3, and the compensation illumination 5-4, which have relatively large thermal output power, are turned off, so that the temperature of the patterning device 1 decreases and moves away from the vicinity of the upper limit of the thermal equilibrium temperature range. The cooling time is T4. Of course, in this step, the second detection illumination 5-1-1 can also be turned off. Since the output power of the light source exhibits certain fluctuations when the light source is turned off and restarted, preferably, the second detection illumination 5-1-1 can remain turned on.

Based on the above embodiment, after S3, the method also includes: repeating S2˜S3 to alternately perform the detection step and the exposure step, wherein the patterning device 1 is maintained within the thermal equilibrium temperature range during the detection step and the exposure step.

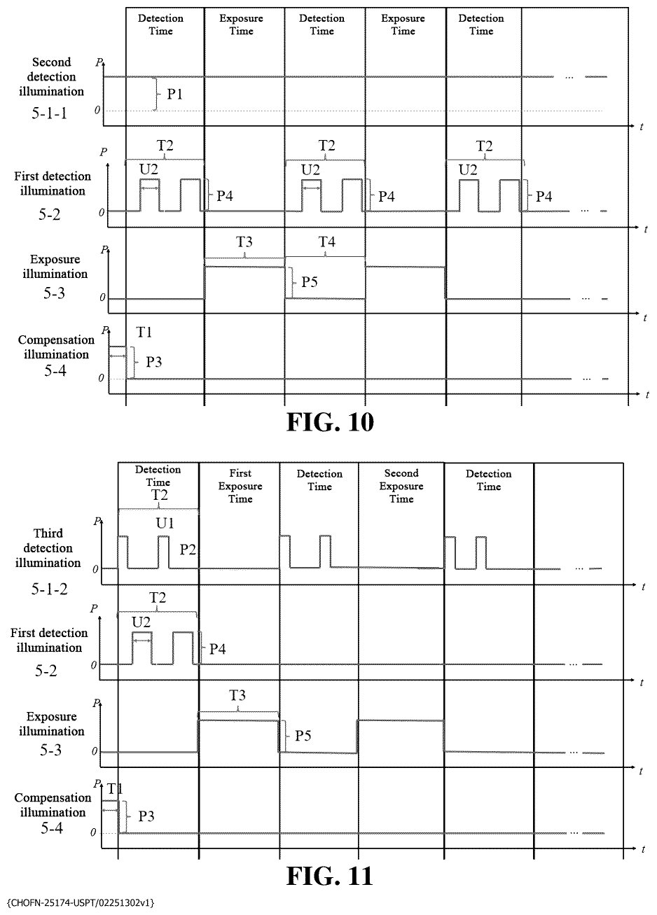

In the above embodiment, after a single position detection is performed on a single patterning device 1, subsequent multiple exposure fields can be processed. If the detection is required again after the end of the single exposure field, the process needs to return to step S2 after step S3 (or step S41 if it exists). The timing switching process is shown in FIG. 10 (sixth solution).

On the basis of the above embodiment, step S2 includes: alternately turning on third detection illumination 5-1-2 and first detection illumination 5-2, wherein a single illumination cycle and a single illumination duration of the third detection illumination 5-1-2 match a single illumination cycle and a single illumination duration of the first detection illumination 5-2. An interference exists between the third detection illumination 5-1-2 and the first detection illumination 5-2, that is, when both the third detection illumination 5-1-2 and the first detection illumination 5-2 are turned on, they interfere with each other and affect the detection results.

Based on the first solution, if multiple detection illuminations interfere with each other and affect the detection results, only one detection illumination is allowed to be present at a given time, and the timing control process is as follows, wherein the third detection illumination 5-1-2 is a coherent detection illumination. The complete process is as follows.

Step S1 includes: turning on the compensation illumination 5-4 at power-on, with the illumination region of the compensation illumination 5-4 being C1×C2, power density being P3, and illumination time being T1; continuously illuminating until the patterning device 1 reaches the thermal equilibrium temperature range W; and then turning off the compensation illumination 5-4.

Step S2 includes: entering the detection illumination activation time interval, in which multiple detection illuminations that interfere with each other are present. In the solution, two coherent detection illuminations are provided, namely the third detection illumination 5-1-2 and the first detection illumination 5-2. In the detection illumination activation time interval, the illumination region of the first detection illumination 5-2 is D1×D2, power density is P4, single illumination cycle is T, single illumination duration is U2, and single field illumination time is T2. After the single field illumination time reaches T2, the first detection illumination 5-2 is turned off. The illumination region of the third detection illumination 5-1-2 covers N×N B1×B2 regions, with a power density of P2, a single illumination cycle of T, and a single illumination duration of U1. After the single field illumination time reaches T2, the third detection illumination 5-1-2 is turned off. The single illumination duration U2 of the first detection illumination 5-2 within the single illumination cycle T should be designed to match the single illumination duration U1 of the third detection illumination 5-1-2, thus ensuring that only one of the first detection illumination 5-2 or the third detection illumination 5-1-2 is activated at any given time to avoid mutual interference. During the single-field illumination time of the first detection illumination 5-2 and the third detection illumination 5-1-2, the temperature of the patterning device 1 is maintained within the thermal equilibrium temperature range.

Step S3 includes: turning on the exposure illumination 5-3, wherein the illumination region of the exposure illumination 5-3 is E1×E2, power density is P5, and single field illumination time is T3; and after the single field illumination time reaches T3, turning off the exposure illumination 5-3. During the switching process between the detection illumination and the exposure illumination 5-3, and in step S3, the temperature of the patterning device 1 is maintained within the thermal equilibrium temperature range.

Based on the above embodiment, after S33, the method also includes: repeating S2˜S3, wherein only the third detection illumination 5-1-2 in S2 is turned on during the repeating process, and the first detection illumination 5-2 is turned off; and alternately performing the detection step and the exposure step, wherein the patterning device 1 is maintained within the thermal equilibrium temperature range during the detection step and the exposure step.

Before the stage 4 drives the substrate 3 to move to the next exposure field and continues the next exposure, relevant parameter detection is performed using the third detection illumination 5-1-2. The illumination region of the third detection illumination 5-1-2 covers N×N B1×B2 regions, with a power density of P2, a single illumination cycle of T, and a single illumination duration of U1. After the single field illumination time reaches T2, the third detection illumination 5-1-2 is turned off; and the process then returns to step S3. If the patterning device 1 is replaced, the process must return to step S1. The timing switching process is shown in FIG. 11 (seventh solution).

The present disclosure introduces compensation illumination, which enables long-term thermal equilibrium of the patterning device. This thermal equilibrium coordinates the illumination modes while ensuring a relatively small temperature fluctuation when switching light fields, thereby controlling the variation range of thermal deformation of the patterning device. During operation, the pattern of the patterning device is maintained in a uniform and stable deformation state. Meanwhile, by rationally distributing the timing, designing the illumination start points and durations, single illumination cycles, and single illumination durations, mutual interference between multiple detection illuminations is avoided. Furthermore, the illumination required for the exposure workflow is seamlessly integrated, improving exposure efficiency, and thereby enhancing throughput.

The present disclosure is further described below through specific embodiments. In the following embodiments, the thermal control method for the above-mentioned patterning device is specifically explained. However, the following embodiments are provided merely for illustrative purposes and are not intended to limit the scope of the present disclosure.

As an example, as shown in FIG. 2, in the near-field lithography system, the patterning device 1 is adsorbed and mounted on the chuck 2, and the substrate 3 is mounted on the stage 4. The patterning device 1 is affected by the thermal load of the first detection illumination 5-2, second detection illumination 5-1-1, third detection illumination 5-1-2, exposure illumination 5-3, and compensation illumination 5-4.

In the present embodiment, a complex three-path detection illumination solution is adopted, wherein one path, the second detection illumination 5-1-1, has low thermal output power, and the other two paths, the third detection illumination 5-1-2 and the first detection illumination 5-2, have high thermal output power and cause mutual interference. The timing sequence is as follows.

Step S1: turning on the second detection illumination 5-1-1 and the compensation illumination 5-4 simultaneously at power-on, wherein the thermal output from the second detection illumination 5-1-1 to the patterning device 1 is small; its illumination region can be determined based on actual needs; and it can remain turned on throughout the operation of the machine, wherein the illumination region of the compensation illumination 5-4 is C1×C2, power density is P3, and illumination time is T1; and continuously illuminating until the patterning device 1 reaches the thermal equilibrium temperature range W, and then turning off the compensation illumination 5-4.

Step S2: entering the detection illumination activation time interval, in which multiple detection illuminations that interfere with each other are present. In the present embodiment, two coherent detection illuminations are provided, namely the third detection illumination 5-1-2 and the first detection illumination 5-2. In the detection illumination activation time interval, the illumination region of the first detection illumination 5-2 is D1×D2, power density is P4, single illumination cycle is T, single illumination duration is U2, and single field illumination time is T2. After the single field illumination time reaches T2, the detection is completed, and the first detection illumination 5-2 is turned off. The illumination region of the third detection illumination 5-1-2 covers N×N B1×B2 regions, with a power density of P2, a single illumination cycle of T, and a single illumination duration of U1. After the single field illumination time reaches T2, the third detection illumination 5-1-2 is turned off. The single illumination duration U2 of the first detection illumination 5-2 within the single illumination cycle T should be designed to match the single illumination duration U1 of the third detection illumination 5-1-2, thus ensuring that only one of the first detection illumination 5-2 or the third detection illumination 5-1-2 is activated at any given time to avoid mutual interference. During the single-field illumination time of the first detection illumination 5-2 and the third detection illumination 5-1-2, the temperature of the patterning device 1 is maintained within the thermal equilibrium temperature range.

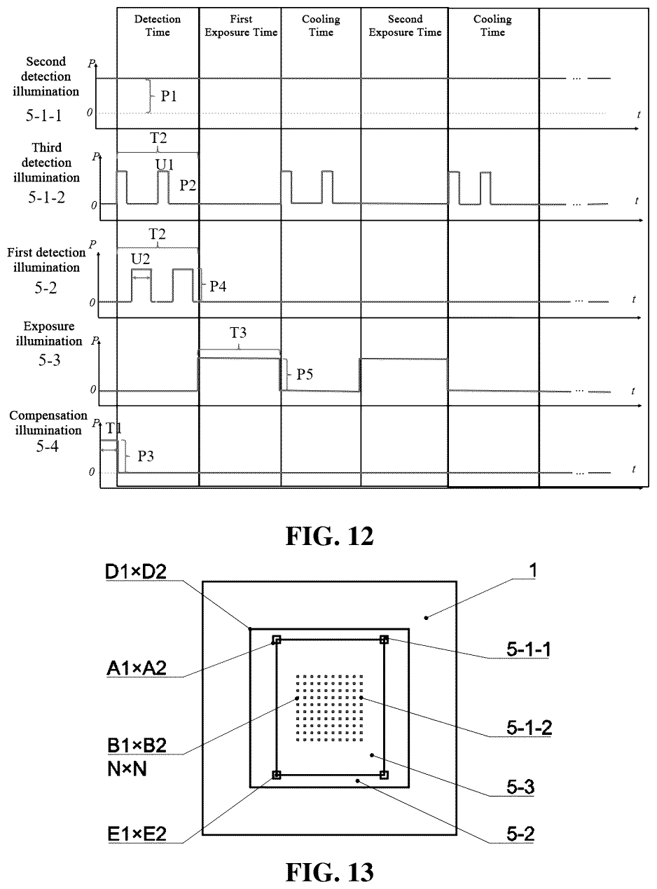

Step S3: turning on the exposure illumination 5-3, wherein the illumination region of the exposure illumination 5-3 is E1×E2, power density is P5, and single field illumination time is T3; and after the single field illumination time reaches T3, turning off the exposure illumination 5-3. During the switching process between the detection illumination and the exposure illumination 5-3, and in step S3, the temperature of the patterning device 1 is maintained within the thermal equilibrium temperature range. As shown in FIG. 12, after turning off the first detection illumination 5-2 and turning on the exposure illumination 5-3, the temperature of the patterning device 1 increases and approaches the upper limit of the thermal equilibrium temperature range, and a cooling process needs to be added.

Step S4: driving the substrate 3 by the stage 4 to move to the next exposure field, continuing the next exposure, performing relevant parameter detection through the third detection illumination 5-1-2, wherein the illumination region of the third detection illumination 5-1-2 covers N×N B1×B2 regions, with a power density of P2, a single illumination cycle of T, and a single illumination duration of U1; after the single field illumination time reaches T2, turning off the third detection illumination 5-1-2; and returning the process to step S3. The timing switching process is shown in FIG. 12. If the patterning device 1 is replaced, the process needs to return to Step S1.

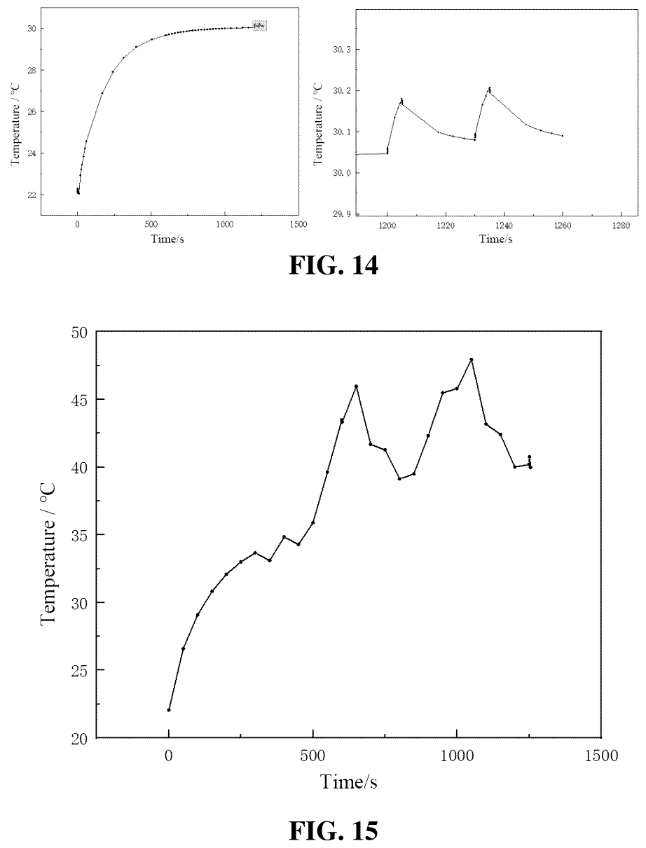

As shown in FIG. 13, a typical illumination condition applied to the upper side of the patterning device 1 in this embodiment is as follows. In the following embodiment, the material of the patterning device 1 is fused quartz, and the illumination region size is the actual size required for detection and exposure under a certain working condition. The power density of each illumination output is obtained through experiments after determining the thermal equilibrium temperature range. The thermal equilibrium temperature range in the embodiment is 30.05-30.2° C. At this time, the Z-direction deformation at the center of the patterning device 1 is 40.9 nm, and the Z-direction deformation at the edge of the compensation region is 21.1 nm. At this time, the surface shape PV within the compensation illumination region of the patterning device is 19.8 nm.
(1) The illumination region of the second detection illumination 5-1-1 was distributed at the four outer vertices of the central region of 25 mm×30 mm (the four-point A1×A2 region in FIG. 13), with a single-point illumination region of 0.5 mm×0.5 mm and a single-point illumination power density of 11000 mW/cm².
(2) The illumination region of the third detection illumination 5-1-2 covered N×N B1×B2 regions, wherein it was distributed in the central region of 20 mm×20 mm and was a 20×20 point array, wherein a single-point illumination region was 0.1 mm×0.1 mm, with a single-point illumination power density of 1000 mW/cm², a single illumination cycle of 0.25 s, and a single illumination duration of 0.06 s.
(3) The illumination region of the compensation illumination 5-4 was distributed within the central region of 40 mm×40 mm, with an illumination power density of 50 mW/cm² and an illumination duration T1 of 1000 s. In this case, the compensation illumination 5-4 directly adopted the illumination components of the first detection illumination 5-2, and when functioning as compensation illumination, it was referred to as compensation illumination.
(4) The illumination region of the first detection illumination 5-2 was D1×D2, distributed within the central region of 40 mm×40 mm, with an illumination power density of 50 mW/cm², a single illumination duration of 0.25 s, a single illumination duration of 0.03 s, and a single-field detection time of 25 s, i.e., the first detection illumination 5-2 is used 100 times within the single-field detection time. After the single-field detection was completed, the first detection illumination 5-2 was turned off.
(5) The illumination region of the exposure illumination 5-3 was E1×E2, distributed within the central region of 25 mm×30 mm, with an illumination power density of 60 mW/cm² and a single-field illumination time of 5 s. As shown in FIG. 14, after turning off the first detection illumination 5-2 and turning on the exposure illumination 5-3, the temperature approached the upper limit of the thermal equilibrium temperature range of 30.2° C., and a cooling process needed to be added. The cooling duration was 25 s, and after cooling, the temperature returned to approximately 30.08° C. within the thermal equilibrium temperature range.

By adopting the thermal control solution of the present disclosure, as shown in the left part of FIG. 14, experimental results under working conditions indicate that with an initial ambient temperature of 22° C., after 1200 seconds from power-on during the exposure process, the compensation illumination of step S1 and the first detection illumination of step S2 are completed, at which point the patterning device 1 has reached a thermal equilibrium state with an overall temperature of 30.05° C. As shown in the right part of FIG. 14, after switching to the exposure illumination 5-3 of step S3, the temperature begins to rise, reaching the vicinity of the upper limit of the thermal equilibrium temperature range of 30.2° C. At this time, the temperature fluctuation gradient is 0.15° C., the Z-direction deformation at the center of the patterning device 1 is 40.9 nm, and the Z-direction deformation at the edge of the compensation illumination region is 21.1 nm, that is, the surface shape PV of the patterning device is 19.8 nm@25 mm×30 mm.

In contrast, without adopting the thermal control solution of the present disclosure, that is, without controlling the timing for turning on detection illumination and exposure illumination, as shown in FIG. 15, the temperature of the patterning device 1 continues to rise, exceeding 40° C. without reaching the thermal equilibrium state. Furthermore, during the exposure process, the temperature fluctuates significantly, with the temperature gradient difference exceeding 9° C. during single field detection and exposure, and the surface shape PV of the patterning device 1 is greater than 36.4 nm@25 mm×30 mm.

The embodiment further provides a method for obtaining timing control.

The main heat-input illuminations are classified into a first detection illumination 5-2, an exposure illumination 5-3, and a compensation illumination 5-4. The compensation illumination 5-4 is configured to heat the patterning device 1 from room temperature to the thermal equilibrium temperature range W, making the temperature of the patterning device 1 more uniform. This avoids the issue where, without temperature control of the patterning device 1, the deformation difference between the center and the edge of the detection region becomes excessively large. The exposure illumination 5-3 is used in the pattern exposure process.
(1) First, the thermal equilibrium temperature range W of the patterning device 1 is determined. The patterning device 1 undergoes thermal deformation, and the relationship between the Z-direction deformation and temperature of the patterning device 1 can be obtained through experiments or simulation. When, at a temperature, the Z-direction deformation ΔZ_{C1×C2} at the edge of the compensation illumination region of the patterning device 1 is greater than or equal to 50% of the Z-direction deformation ΔZ at the center of the patterning device, this temperature can be selected as the thermal equilibrium temperature range W.
(2) After the illumination regions D1×D2, E1×E2, and C1×C2 of the first detection illumination 5-2, the exposure illumination 5-3, and the compensation illumination 5-4 are actually determined, and the power density and illumination duration input by the first detection illumination 5-2, the exposure illumination 5-3, and the compensation illumination 5-4 are calculated using a simulation model or experiment, under the condition that the temperature of the patterning device 1 is maintained within the thermal equilibrium temperature range W.

The present disclosure adopts the core concept of achieving thermal equilibrium through mutual energy compensation, solving the problem that high energy transfer cannot be achieved by the patterning device within a short time. It provides an effective thermal control means for the patterning device, enabling the pattern of the patterning device to maintain stable deformation during operation and avoiding deformation of the exposed pattern caused by uneven heating.

The above specific embodiments further describe the objectives, technical solutions, and beneficial effects of the present disclosure in detail. It should be understood that the above description is merely specific embodiments of the present disclosure and is not intended to limit the present disclosure. Any modifications, equivalent substitutions, improvements, etc., made within the spirit and principle of the present disclosure shall be included within the scope of protection of the present disclosure.

1. A thermal control method for a patterning device, comprising:
S1, turning on compensation illumination, after heating a patterning device to a thermal equilibrium temperature range, turning off the compensation illumination, wherein an illumination region area of the compensation illumination is S_{C1×C2};
S2, turning on first detection illumination, turning off the first detection illumination after a detection step is completed, wherein an illumination region area of the first detection illumination is S_{D1×D2}; and
S3, turning on exposure illumination, turning off the exposure illumination after an exposure step is completed, wherein an illumination region area of the exposure illumination is S_{E1×E2},
where S_{C1×C2}≥S_{D1×D2}≥S_{C1×E2}, wherein during a switching process among S1, S2, and S3, a temperature of the patterning device is maintained within the thermal equilibrium temperature range; and within the thermal equilibrium temperature range, a Z-direction deformation ΔZ_{C1×C2} at an edge of the compensation illumination region is greater than or equal to 50% of the Z-direction deformation ΔZ at a center of the patterning device.

2. The thermal control method for a patterning device according to claim 1, before the S1, further comprising:
S0, determining the thermal equilibrium temperature range according to a relationship between the deformation and the temperature of the patterning device.

3. The thermal control method for a patterning device according to claim 1, after the S3, further comprising:
S4, turning on the exposure illumination in a next exposure field, wherein the temperature of the patterning device is maintained within the thermal equilibrium temperature range during an illumination duration of the exposure illumination, and
a time interval between preceding and succeeding exposure illuminations is T₅.

4. The thermal control method for a patterning device according to claim 3, before the S4, further comprising:
S41, turning off all illumination, allowing the patterning device to cool, wherein a cooling duration is T₄; and T₄ comprises T₅ or T₄ does not comprise T₅.

5. The thermal control method for a patterning device according to claim 1, after the S3, further comprising:
repeating S2˜S3 to alternately perform the detection step and the exposure step, wherein the patterning device is maintained within the thermal equilibrium temperature range during the detection step and the exposure step.

6. The thermal control method for a patterning device according to claim 1, wherein the S1 further comprises:
turning on second detection illumination when turning on the compensation illumination, wherein the second detection illumination remains turned on during S2˜S3;
a thermal output power of the second detection illumination is much lower than a thermal output power of the first detection illumination and no interference exists between the second detection illumination and the first detection illumination.

7. The thermal control method for a patterning device according to claim 6, after the S3, further comprising:
S41, turning off all illumination, allowing the patterning device to cool, wherein a cooling duration is T₄; and
S4, turning on the exposure illumination in a next exposure field, wherein the temperature of the patterning device is maintained within the thermal equilibrium temperature range during an illumination duration of the exposure illumination; a time interval between preceding and succeeding exposure illuminations is T₅; and
T₄ comprises T₅ or T₄ does not comprise T₅.

8. The thermal control method for a patterning device according to claim 6, after the S3, further comprising:
repeating S2˜S3 to alternately perform the detection step and the exposure step, wherein the patterning device is maintained within the thermal equilibrium temperature range during the detection step and the exposure step.

9. The thermal control method for a patterning device according to claim 1, wherein the S2 further comprises:
alternately turning on third detection illumination and first detection illumination, wherein a single illumination cycle and a single illumination duration of the third detection illumination match a single illumination cycle and a single illumination duration of the first detection illumination, wherein an interference exists between the third detection illumination and the first detection illumination.

10. The thermal control method for a patterning device according to claim 9, after the S3, further comprising:
repeating S2˜S3, wherein only the third detection illumination in S2 is turned on during the repeating process, and the first detection illumination is turned off; and alternately performing the detection step and the exposure step, wherein the patterning device is maintained within the thermal equilibrium temperature range during the detection step and the exposure step.
